(19) United States
(12) Patent Application Publication
(10) Pub. No.: US 2011/0309853 A1
(43) Pub. Date: Dec. 22, 2011

(54) SECTIONAL TEST PROBE ASSEMBLY FOR ELECTRIC METER

(75) Inventor: Po-Chao TAN, Chung-Ho City (TW)

(73) Assignee: Brymen Technology Corporation

(21) Appl. No.: 12/817,263

(22) Filed: Jun. 17, 2010

(51) Int. Cl. G01R 31/02

(52) U.S. Cl. 324/755.01; 324/754.08

(57) ABSTRACT

The test probe assembly of the invention is used for an electric meter such as a multimeter or the like. The electric meter has a main body. The test probe assembly includes a pair of insulated rods, a pair of probe tips and a pair of leads. The insulated rods are separately provided with two corresponding engaging portions, so that the insulated rods can be combined or detached. One end of each probe tip is fixed in one of the insulated rods and the other ends are protrudent. The leads connect between the insulated rods and main body. The combination or detachment of the test probe assembly may form a variety of configurations for different measured objects.

### BACKGROUND OF THE INVENTION

1. Technical Field

The invention generally relates to electric meters, particularly to test probes thereof.

2. Related Art

Traditionally, an electric meter, such as multimeter or voltmeter, is composed of a main body and two test probes. The test probes are used to contact the object to be measured and a reading can by shown on the main body.

Crocodile clips, retractable hook clips, and pointed probes are the three most common test probes. The different types of test probes may be exchanged for various objects under test.

However, a user may not carry all kinds of test probes at hand anytime and anywhere. A measure process can not be proceeded if a required type of test probe is absent. It will be inconvenient for users.

### SUMMARY OF THE INVENTION

An object of the invention is to provide a sectional test probe assembly, whose two test probes can be combined or detached with each other. Thus the test probe assembly may form a variety of configurations for different measured objects.

Another object of the invention is to provide a sectional test probe assembly, which is adjustable in angle when the test probes are combined. It is convenient and useful.

To accomplish the above objects, the invention provides a sectional test probe assembly for an electric meter. The electric meter has a main body. The test probe assembly of the invention includes a pair of insulated rods, a pair of probe tips and a pair of leads. The insulated rods are separately provided with two corresponding engaging portions, so that the insulated rods can be combined or detached. One end of each probe tip is fixed in one of the insulated rods and the other ends are protrudent. The leads connect between the insulated rods and main body. The combination or detachment of the test probe assembly may form a variety of configurations for different measured objects.

In comparison with a traditional test probe, the two test probes of the invention are separately provided with two corresponding engaging portions, so that the insulated rods can be combined or detached. The insulated rods are flexible and bendable. They may be detached into two separate ones or combined into an integer.

### BRIEF DESCRIPTION OF THE DRAWINGS

FIG. 1 shows the test probe assembly and the main body of the electric meter of the invention;

FIG. 2 is a perspective view of the test probe assembly in a combined status;

FIG. 3 is a perspective view of the test probe assembly in a detached status ;

FIG. 4 shows the second embodiment of the invention;

FIG. 5 shows the second embodiment with a crocodile clip;

FIG. 6 shows the third embodiment of the invention; and

FIG. 7 shows the fourth embodiment of the invention;

### DETAILED DESCRIPTION OF THE INVENTION

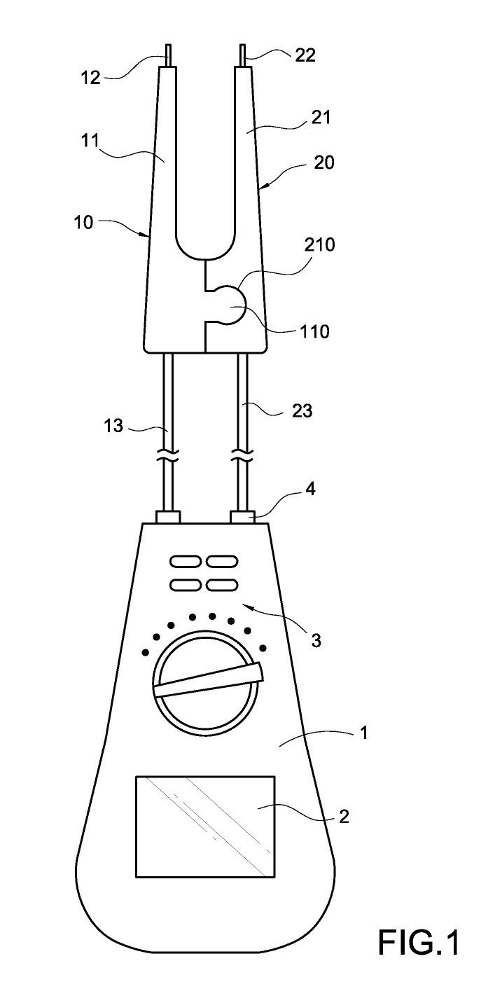

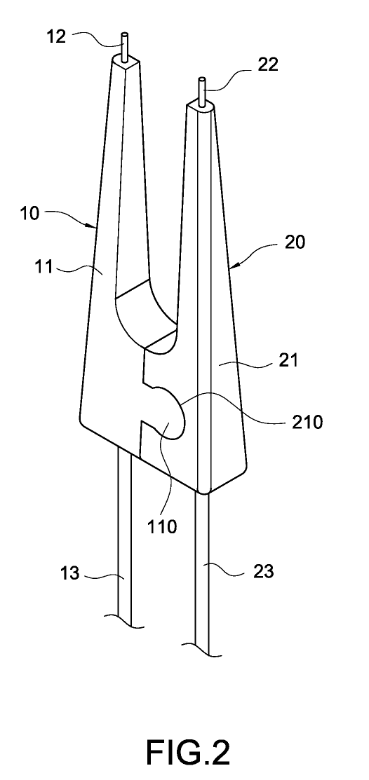

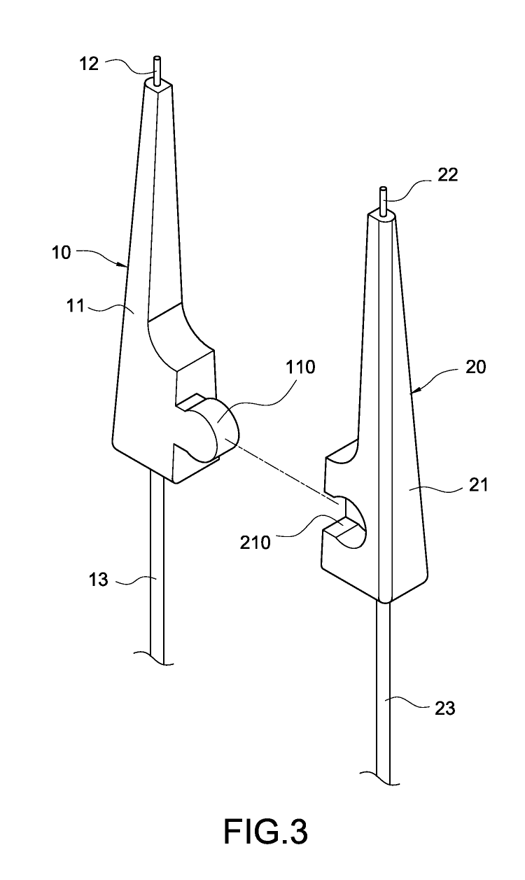

Referring to FIGS. 1-3, the sectional test probe assembly of the invention is composed of a pair of test probes 10, 20 which connect to a main body 1.

The main body 1 is a substantial cuboid, whose façade is provided with a display 2 for showing readings, battery capacity or other information. There are some bottoms 3 beside the display 2. The top of the main body 10 is disposed with a connecting portion 4.

The test probes 10, 20 connect to the connecting portion 4 and include a pair of insulated rods 11, 21, a pair of probe tips 12, 22 and a pair of leads 13, 23. The insulated rods 11, 21 are made of flexible material such as rubber. One side of each of the insulated rods 11, 21 is provides with an engaging portion 110, 210. The two engaging portions 110, 210 are corresponding in shape and can engage with each other. The insulated rods 11, 21 may be combined into an integer or detached into two individuals. In the embodiment shown in the figures, the engaging portions 110, 210 are a protrusion and a recess, respectively.

The probe tips 12, 22 are made of conductive material. One end of each of the probe tips 12, 22 are planted in one of the insulated rods 11, 12, and the other ends are protrudent from the insulated rods 11, 12. The two leads 13, 23 electrically connect between the probe tips 12, 22 and connecting portion 4 of the main body 1, so that the probe tips 12, 22 can form a part of circuit of the main body 1.

The two test probes 10, 20 may be combined into an integral fork-shaped test probe. And the combined test probe 10, 20 may be slightly bent to satisfy practical requirements. On the other hand, the two test probes 10, 20 may be detached into two individuals, so that a user may separately use the test probes 10, 20.

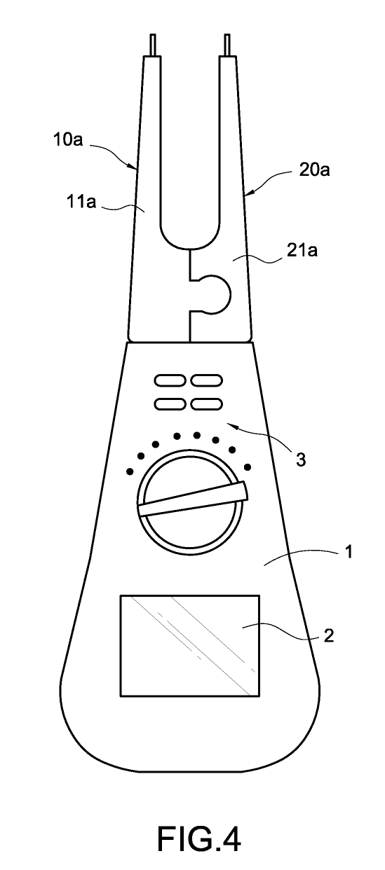

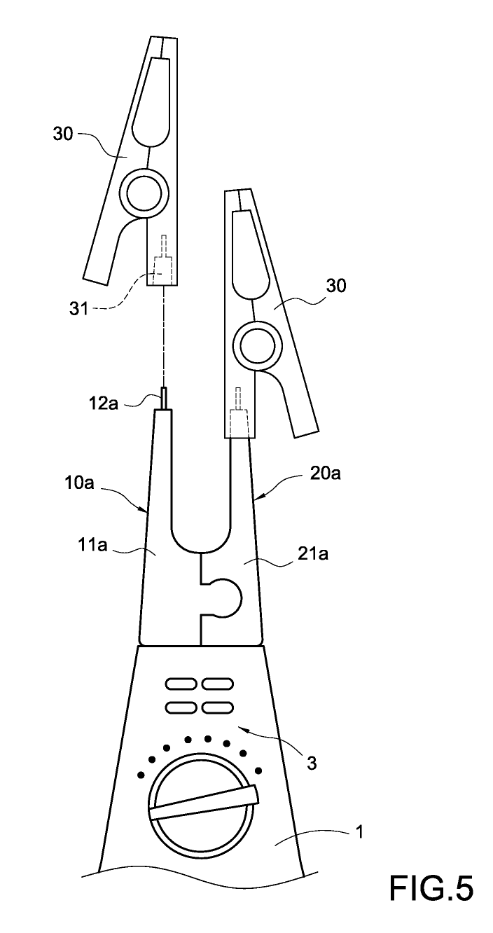

Referring to FIG. 4, which shows the second embodiment of the invention, it differs from the first embodiment by the fixed test probes 10a, 20a. In other words, one of the test probes 10a, 20a is fixedly mounted on the main body 1a. In this embodiment, the insulated rod 21a of the test probe 20a is integratedly formed with the main body 1a. Referring to FIG. 5, the invention may further include a pair of crocodile clips 30 mounted on the probe tips 12a. There is a receiving hole 31 in the crocodile clip 30. The crocodile clip 30 may be fixed by inserting the probe tip 12a into the receiving hole 31, so that the probe tip 12a can conductively connect the crocodile clip 30.

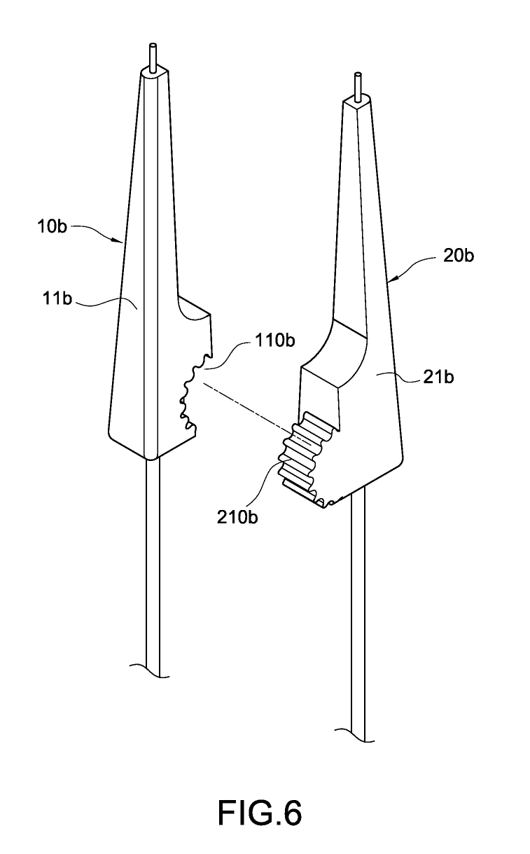

Please refer to FIG. 6, which shows the third embodiment of the invention. In this embodiment, the engaging portions 110b, 210b of the test probes 10b, 20b are a toothed recess and a toothed protrusion. The two toothed engaging portions 110b, 210b may be engaged with each other and the included angle between the insulated rods 11b, 21b may be adjusted.

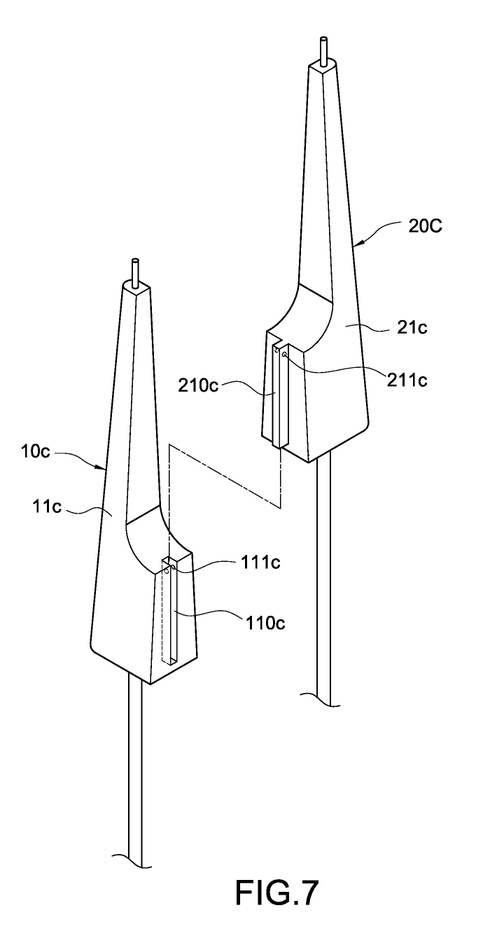

Please refer to FIG. 7, which shows the fourth embodiment of the invention. In this embodiment, the engaging portions 110c, 220c are a slot and a rail. Preferably, a positioning hole 111c and a positioning point 211c may be formed in the slot 110c and the rail 210c, respectively. The positioning hole 111c may be embedded by the positioning point 211c for enhancing the engaging effect.

It will be appreciated by persons skilled in the art that the above embodiments have been described by way of example only and not in any limitative sense, and that various alterations and modifications are possible without departure from the scope of the invention as defined by the appended claims.

What is claimed is:

1. A sectional test probe assembly for an electric meter having a main body, comprising:
a pair of insulated rods, being separately provided with two corresponding engaging portions for being combined or detached with each other;
a pair of probe tips, one end of each probe tip being fixed in one of the insulated rods and the other ends being protrudent; and
a pair of leads, connecting between the insulated rods and the main body.

2. The test probe assembly of claim 1, wherein the insulated rods are made of flexible material.

3. The test probe assembly of claim 2, wherein the insulated rods are made of rubber.

4. The test probe assembly of claim 1, wherein the engaging portions are a protrusion and a recess.

5. The test probe assembly of claim 4, wherein the protrusion and the recess are with teeth.

6. The test probe assembly of claim 1, wherein the engaging portions are a rail and a slot.

7. The test probe assembly of claim 6, further comprising a positioning hole and a positioning point formed in the slot and the rail, respectively.

8. The test probe assembly of claim 1, wherein one of the insulated rods is integratedly formed on the main body.

9. The test probe assembly of claim 1, wherein the probe tips are made of conductive material.

10. The test probe assembly of claim 1, further comprising a pair of crocodile clips mounted on the probe tips.

11. The test probe assembly of claim 1, wherein each of the crocodile clips is provided with a receiving hole for being embedded by the probe tips.
